(19) United States
(12) Patent Application Publication
(10) Pub. No.: US 2007/0189888 A1
(43) Pub. Date: Aug. 16, 2007

(54) Manipulator

(76) Inventor: Thomas H. Tanner, Long Lake, WI (US)

Correspondence Address: BOYLE FREDRICKSON NEWHOLM STEIN & GRATZ, S.C., 250 E. WISCONSIN AVENUE, SUITE 1030, MILWAUKEE, WI, 53202, US

(21) Appl. No.: 11/673,227

(22) Filed: Feb. 9, 2007

Related U.S. Application Data
(60) Provisional application No. 60/771,814, filed on Feb. 9, 2006.

(51) Int. Cl. H01L 21/687

(52) U.S. Cl. 414/672

(57) ABSTRACT

The present invention is a manipulator arm including a pickup head secured to one end of the arm. The pickup head on the manipulator arm includes a number of vacuum cups directed to engage and secure an object to the pickup head for movement with the manipulator arm. The total height of the pickup head does not exceed fourteen (14) inches, such that the pickup head can be utilized to reach into existing warehouse racks with sufficient clearance to lower and raise the pickup head and an object secured to the pickup head.

### CROSS-REFERENCE TO RELATED APPLICATIONS

This application claims priority under 35 U.S.C. §119(e) from U.S. Provisional Patent Application Ser. No. 60/771,814, filed Feb. 9, 2006, which is incorporated by reference herein in its entirety.

### FIELD OF THE INVENTION

The present invention relates to manipulators, more specifically to a manipulator including a manipulator arm having a reduced clearance height.

### BACKGROUND OF THE INVENTION

To enable individuals to effectively move heavy objects from one location to another in various environments, a number of different manipulators have been developed that allow the individual to easily pick up and move objects of this type. These manipulators are of varied configurations, depending upon a particular environment in which the objects are located.

In particular, with regard to objects stored in warehouses on racks elevated above the floor of the warehouse, most prior art manipulators do not enable the manipulator to reach into the racks and grasp items positioned on the racks, especially when the racks are full of items. The reason for this is that the manipulator arm and/or grasping attachment head disposed on the arm do not provide sufficient clearance for the manipulator and head to reach into the racks above the items positioned on the racks and grasp one or more of the items for removal. As a result, it is often necessary or an individual to manually reach into a storage rack and grasp one or more items to be moved, which can put the individual at a much higher risk for injury, especially in those situations where the storage rack in which the items are disposed is positioned above floor level.

Therefore, it is desirable to develop a gripping head and manipulator arm that can optionally be utilized on conventional lift trucks in any warehouse environment that is able to reach into storage racks in which a number of objects or items are positioned and grasp and maneuver the objects positioned on the racks as necessary.

### SUMMARY OF THE INVENTION

According to a primary aspect of the present invention, a manipulator including a manipulator arm is provided where the manipulator arm includes a head having a vacuum gripping mechanism disposed on the head. The gripping mechanism and the head are designed to have a relatively low overall height, enabling the head to be moved directly into the racks above the objects stored on the racks with enough clearance to subsequently lower the head into contact with the objects. The gripping mechanism on the head can then be activated in order to enable the gripping mechanism to grasp and hold the object to be removed from the rack. Once the object is securely held by the gripping mechanism, the manipulator can be moved to withdraw the head and the object from within the rack.

According to another aspect of the present invention, the manipulator arm and head can be retrofit on a number of different lift truck models in order to enable existing lift trucks to be modified for use with the manipulator arm.

Numerous other aspects, features, and advantages of the present invention will be made apparent from the following detailed description taken together with the drawing figures.

### BRIEF DESCRIPTION OF THE DRAWINGS

The drawings illustrate the best mode currently contemplated as practicing the present invention.

In the drawings:

FIG. 1 is a side plan view of a first embodiment of the manipulator of the present invention;

FIG. 2 is a side plan view of a second embodiment of the manipulator of the present invention;

FIG. 3 is a side plan view of a third embodiment of the manipulator of the present invention;

FIG. 4 is a partially broken away side plan view of the manipulator arm of FIG. 1;

FIG. 5 is a partially broken away top plan view of the gripping head of the manipulator arm of FIG. 1;

FIG. 6 is a top plan view of a fourth embodiment of the manipulator of the present invention;

FIG. 6A is a partially broken away, top plan view of the gripping head of the manipulator arm of FIG. 6;

FIG. 7 is a top plan view of the manipulator arm of FIG. 6 in an extended, use position;

FIG. 8 is a top plan view of the manipulator arm of FIG. 6 in a partially extended position;

FIG. 9 is a top plan view of the manipulator arm of FIG. 6 in a first loading position;

FIG. 10 is a top plan view of the manipulator arm of FIG. 6 in a second loading position;

FIG. 11 is a top plan view of a fifth embodiment of the manipulator of the present invention;

FIG. 12 is a top plan view of one of the manipulators arms of FIG. 11 in an extended, use position;

FIG. 13 is a side plan view of a sixth embodiment of the manipulator of the present invention;

FIG. 14 is a partially broken away side plan view of the manipulator arm of FIG. 13 in a first use position; and

FIG. 15 is a partially broken away side plan view of the manipulator arm of FIG. 13 in a second use position.

### DETAILED DESCRIPTION OF THE INVENTION

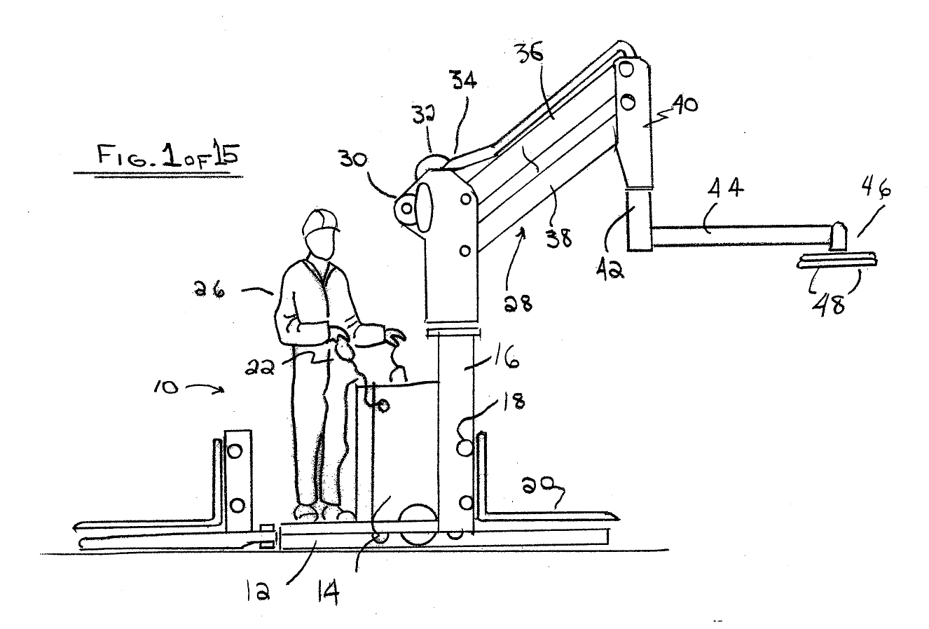

With regard to the drawing figures in which like reference numerals designate like parts throughout the disclosure, a fork truck used in moving objects is illustrated generally at 10 in FIG. 1. The fork truck 10 can be any suitable fork or lift truck or similar apparatus, and includes a wheeled central platform 12 on which is disposed a main controller and counterweight unit 14. Adjacent the controller/counterweight 14, the platform 12 also supports a lift mast 16 to which is secured a carriage 18 on which are disposed a pair of forks 20. The controller/counterweight 14 is also operably connected to a manipulator control 22 and a steering control 24 that enable an operator 26 to operate the fork truck 10 as well as a manipulator arm 28 operably connected to the lift mast 16.

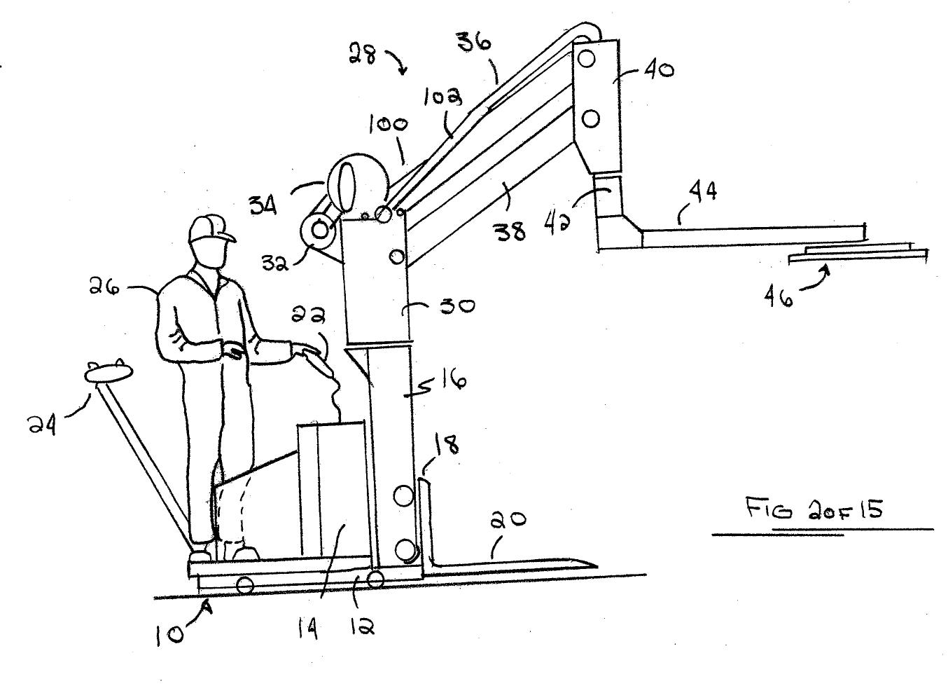

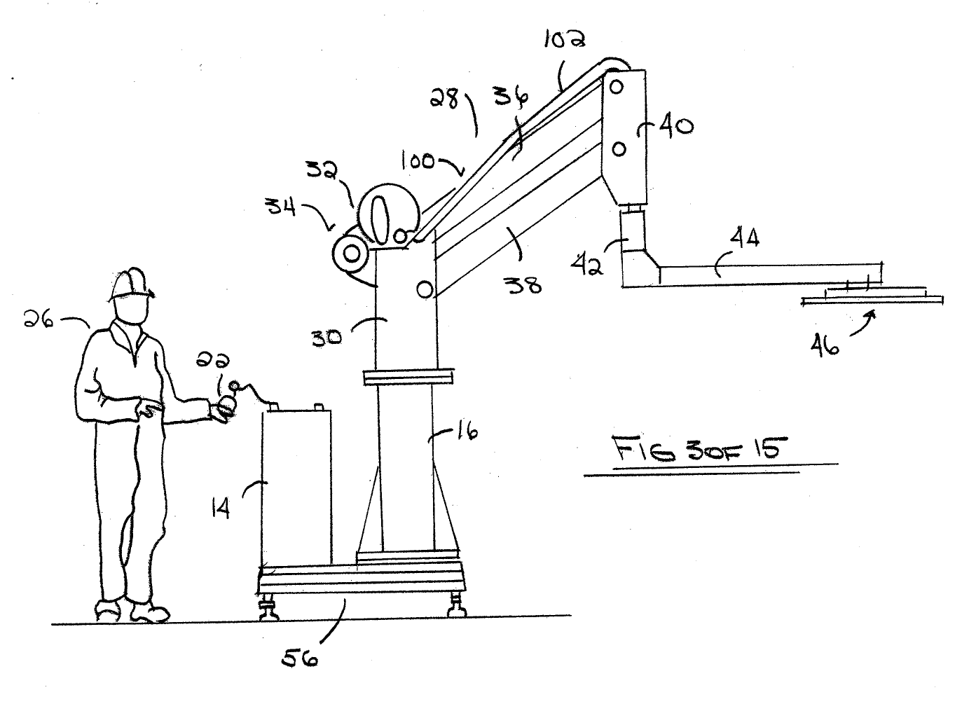

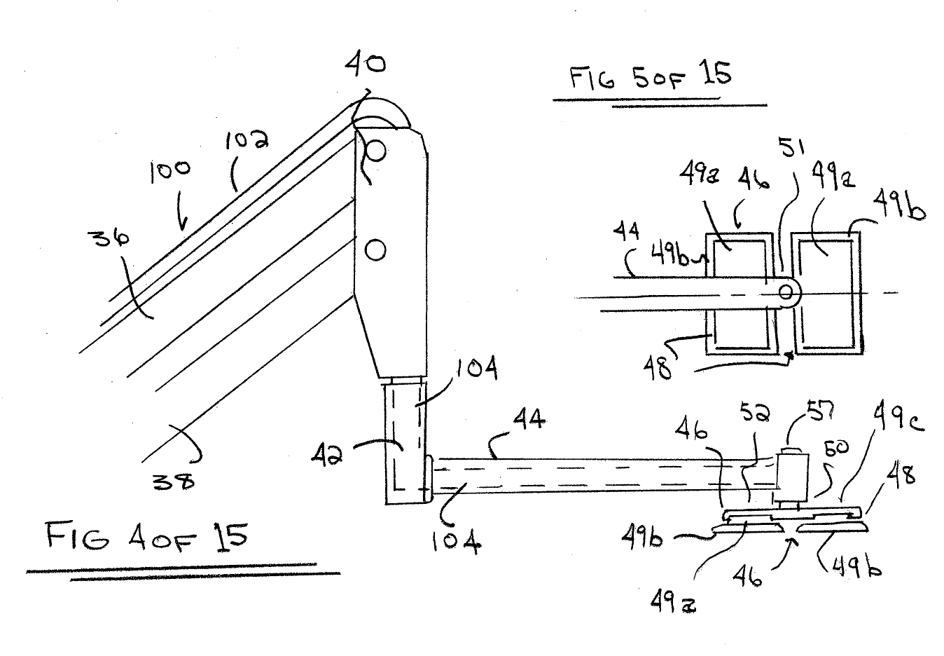

Referring now to FIGS. 1-5, a manipulator arm 28 is illustrated that includes a first section 30 that is operably connected to the lift mast 16 and on which a motor/compressor 32 and control box 34 are mounted. However, the motor/compressor 32 and control box 34 can also be mounted in other locations on the arm 28 or lift truck 10, as desired. The control box 34 controls the operation of the motor/compressor 32 and can be itself controlled utilizing control 22 connected directly to the control box 34 or to the controller 14, which, in turn, can be operably connected to the control box 34.

Two parallel links 36 and 38 are pivotally connected to the first section 30 at one end and to a second section 40 at the opposite end. The pivotal connection of the links 36 and 38 between the sections 30 and 40 allows the links 36 and 38 to vertically move the second section 40 with respect to the first section 30. However, other suitable connections as are known in the art can also be used to connect the first section 30 and the second section 40 such that the second section 40 is movable relative to the first section 30.

The second section 40 also includes a telescoping shaft 42 extending outwardly from the second section 40 opposite the links 36 and 38, and to which is secured a lift arm 44. The shaft 42 is preferably formed as a hydraulic or pneumatic cylinder, such that the shaft 42 can be moved with respect to the second section 40 by the operation of the motor/compressor 32. The control box 34 also allows an operator to control the movement of the shaft 42 by controlling the operation of the motor/compressor 32 to extend or retract the shaft 42 from the second section 40. This can be accomplished by simply manually moving the shaft 42 and second section 40 by in the embodiment of the manipulator arm 28 where the various components of the arm 28 are counterbalanced and not electrically or mechanically controlled, or by utilizing a suitable controller in the embodiment where the arm 28 is mechanically or electrically controlled.

The shaft 42 is connected opposite the second section 40 to a lift arm 44. The lift arm 44 extends outwardly from the shaft 42 generally perpendicular to the shaft 42, and is rotatably connected to the shaft 42. Alternatively, the lift arm 44 can be fixed to the shaft 42 and the shaft 42 can be rotatably secured to the second section 40. In either configuration, after or simultaneously with the positioning of the second section 40 and shaft 42 with respect to the lift truck 10, the lift arm 44 can be rotated with respect to the shaft 42 through an angle of up to 360°, and preferably at least 220°.

Opposite the shaft 42, the lift arm 44 is operably connected to a gripping head 46 on which are disposed a pair of vacuum cups 48 pivotally mounted to a central support 50 extending across a frame 52. The cups 48 each include a central rigid member or plate 49a, and a flexible gasket 49b that surrounds the plate 49a. The gasket 49b is preferably a porous membrane that allows sufficient air flow or suction through the membrane from the motor/compressor 22 to enable the cups 48 to engage and pick up items having porous substrates, such as cardboard boxes or paper bags.

The head 46 also includes a housing or manifold 51 that extends upwardly from the central support 50 and that is pivotally connected to the lift arm 44 to enable the entire head 46 to rotate with respect to the lift arm 44. Preferably the head 46 can rotate through an angle of up to 360°, and preferably at least 180°, to enable the head 46 to be aligned with an item (not shown) positioned on the rack in any configuration. In order to allow the entire head 46 to be positioned within a storage rack (not shown) above items positioned therein without striking the upper end of the rack, particularly when the rack is loaded to capacity, the overall height of the head 46 is formed to be less than fourteen (14) inches, and preferably less than thirteen and one half (13.5) inches. Most preferably, the head 34 has an overall height of between seven (7) and twelve (12) inches, with a height of approximately eight (8) inches being especially preferred to give the most clearance in filled conventional storage racks. Thus, the entire head 46, including the housing 51 and the vacuum cups 48 has sufficient clearance to be moved into a storage rack and positioned over one or more items in the storage rack. In addition, this height for the head 46 also enables each storage rack to accommodate one to two additional layers of items therein, increasing the usable space within each rack as opposed to conventional manipulator heads.

To further enable the head 46 to both have the reduced clearance described previously and be capable of picking up items disposed within a storage rack using the vacuum cups 48, a vacuum channel 100 formed at least partially of a flexible tube 102 that is connected at one end to the motor/compressor 32 that supplies the vacuum force though the channel 100. The tube 102 extends from the motor/compressor 32 to the second section 40. Within the second section 40, the tube 102 can terminate and be connected to an internal conduit 104 formed in the second section 40, or can be threaded through or otherwise attached to the second section 40. If the second section 40 includes the conduit 104, the conduit can be formed to extend downwardly through the shaft 42 and into the lift arm 44. The conduit 104 then connects to the housing 51 where the vacuum supplied by the motor/compressor 32 can be transmitted to the vacuum cups 48 to pick up he items. Alternatively, where the tube 102 is used, the tube 102 can be connected to the exterior of the section 40, the shaft 42 and the arm 44 prior to connection to the vacuum cups 48.

In operation, when the operator 26 desires to remove an object using the manipulator arm 28, the operator 26 steps onto the platform 12 of the truck 10 and uses the steering control 24 to move the truck 10 into the desired location. The operator 26 then secures fork truck 10 and moves the manipulator arm 28 into position to grasp the object. In doing so, the operator 26 moves the manipulator arm 28 into a position where the head 46 is disposed on the object to be moved, such as by utilizing the manipulator control 22, for example, and operates the manipulator control 22 to activate the vacuum cups 48 and grasp the object. Once the object has been grasped by the cups 48 on the head 46, the operator 26 utilizes the control 22 to raise the head 46 and object secured to the head 46, and subsequently pivot the manipulator arm 28 into a position where the object secured to the head 46 is disposed above the forks 20. The operator uses the control 22 to disengage the head 46 and allow the object to be positioned on the forks 20.

Additionally, when not in use, a cradle 54 disposed on the first section 30 receives the lift arm 44 and the head 46 in order to secure the manipulator arm 28 to the truck 10. Further, the movement of the arm 28 can be done using the controller 22, instead of the operator 26 physically moving the arm 28 using the links 36 and 38 and counterweight 14. Also, the arm 28 can be mounted to a stationary and/or lift truck-movable platform 56, as best shown in FIG. 3, and instead of being part of the original construction of the lift truck 10, can be retrofit onto an existing truck.

In another embodiment of the present invention, best shown in FIGS. 6-11, the manipulator arm 128 is disposed on a lift truck 110. The arm 128 includes a first section 130 rotatably mounted to the lift truck 110, and a second section 132 rotatably mounted to the first section 130. The first section 130 is illustrated as being disposed above the second section 132, but this configuration can also be reversed, or the sections 130 and 132 can be connected to one another such that they are coplanar, if desired. The section 130 and 132 of the arm 128 can be moved through the operation of a suitable mechanism (not shown) disposed in the lift truck 110 can operably connected to the sections 130 and 132, or the sections 130 and 132 can be counterbalanced to be positioned by the movement of the sections 130 and 132 by an individual grasping and moving the sections 130 and 132. In either construction, the second section 132 can be rotated through an angle of up to 360° with regard to the first section 130.

Looking now at FIGS. 6 and 6A, the second section 132 includes a gripping head 134 rotatably mounted to the second section 132 opposite the first section 130 and can rotate through an angle of up to 360° with respect to the second section 132. The gripping head 134 is formed similarly to the head 46 in the previous embodiment, with a pair of vacuum cups 136 connected to a manifold 138 having the same clearance or height measurements as the previous embodiment. Also, the cups 136 receive the vacuum required to operate the cups 136 through the arm sections 130 and 132 from the lift truck 110, in a known manner. In addition, the head 134 includes a handle bar 140 that extends around the entire periphery of the vacuum cups 136 to enable the head 134 to be easily grasped and maneuvered by an operator. The head 134 may also include a secondary handle bar 141 secured to the second portion 132 to assist in initially positioning the head 134 over an item to be engaged and picked up with the head 134.

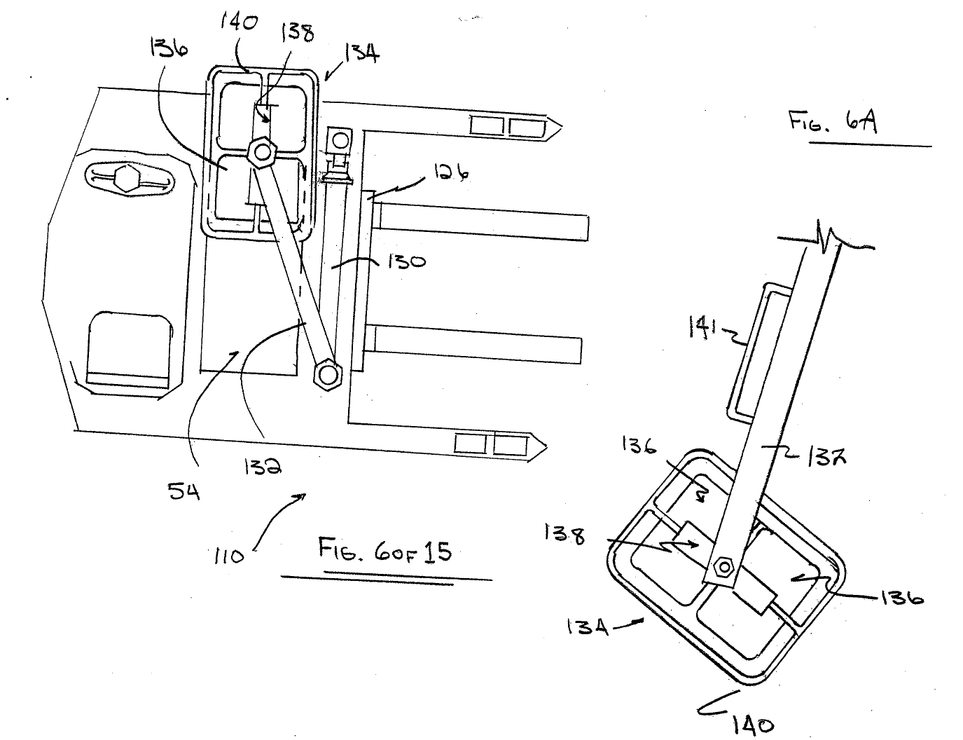

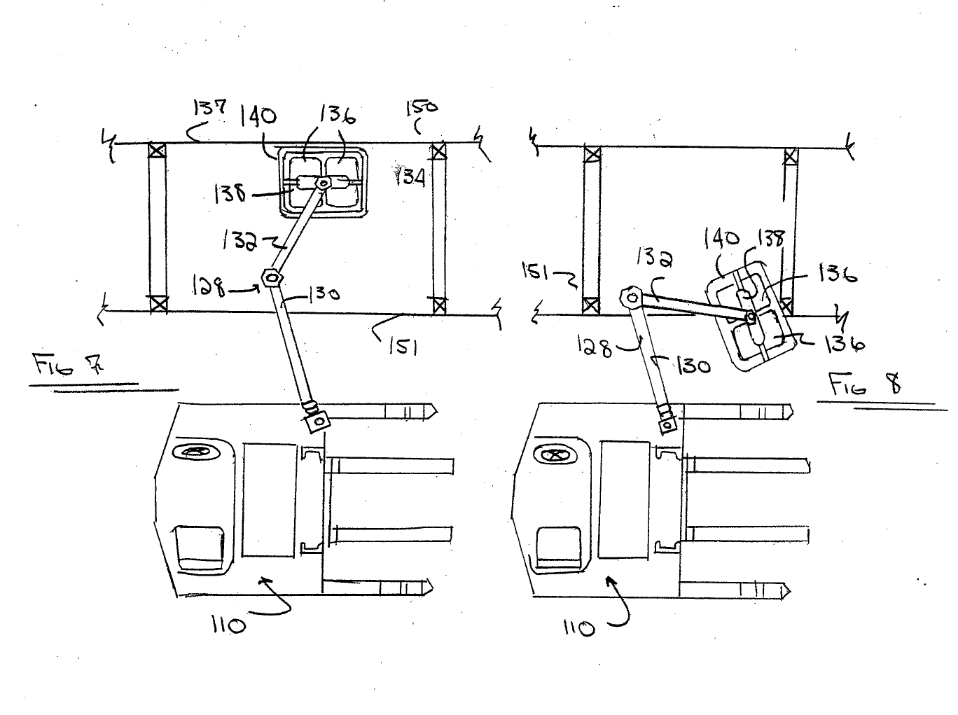

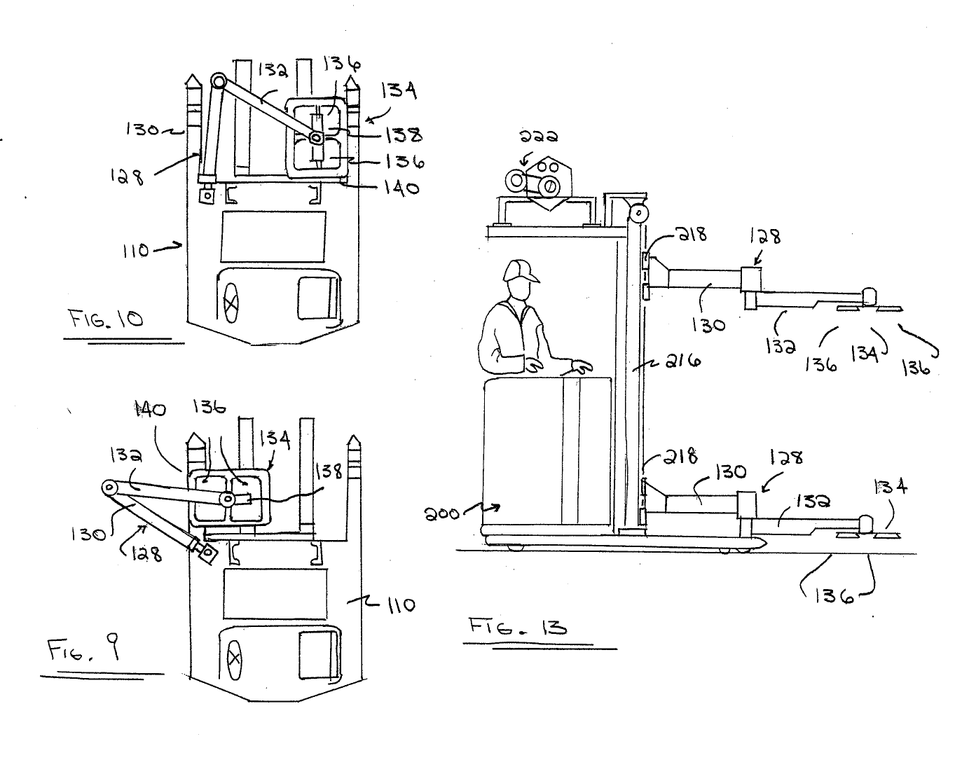

In FIG. 6, the manipulator arm 128 is illustrated in the parked, or non-use position. FIGS. 7 and 8 illustrate how the arm 128 is extended from the lift truck 110 into a storage rack 150 including front and rear cross beam pallet supports 151 in order to position the head 134 above and in contact with the item to be moved. Once grasped by the head 134, as shown in FIGS. 9 and 10, the head 134 can then be repositioned by the operator 26 to load the item where desired, such as onto a pallet (not shown) carried by the lift truck 110 on which the manipulator arm 128 is secured.

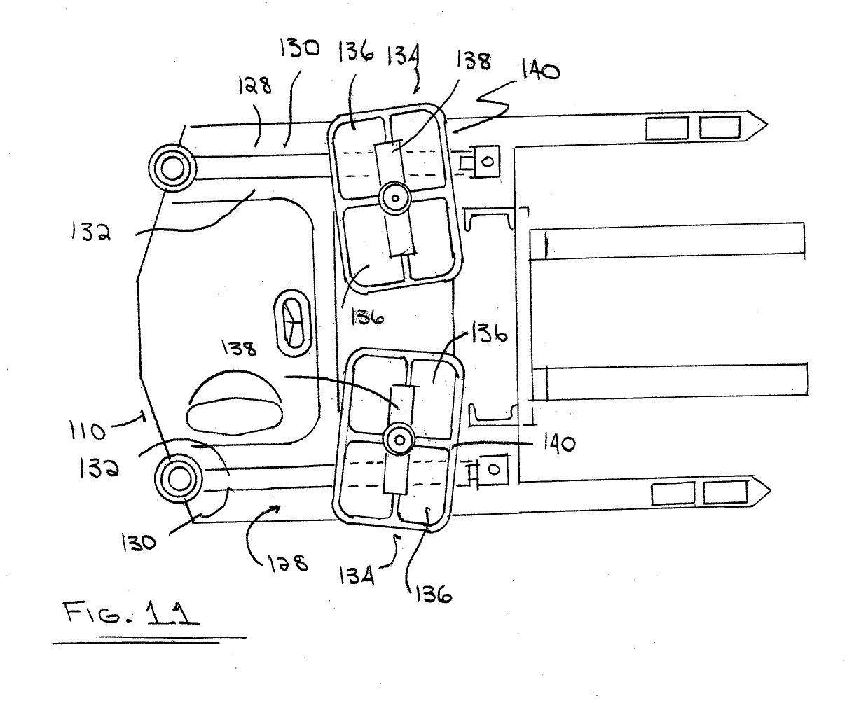

FIGS. 11 and 12 illustrate still another embodiment of the present invention where a pair of manipulator arms 128 are mounted to opposite sides of a lift truck 110, for use either separately or together in a manner similar to that described for the previous embodiment.

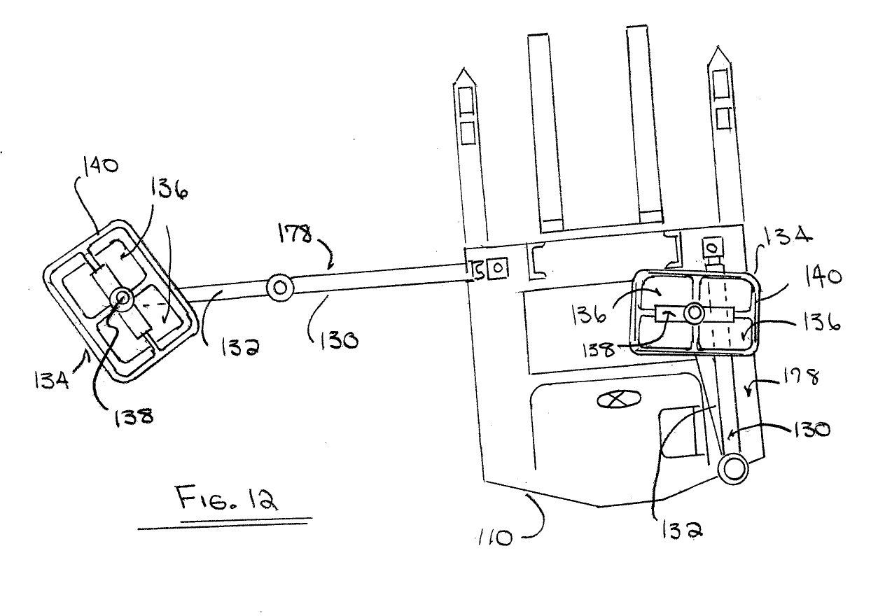

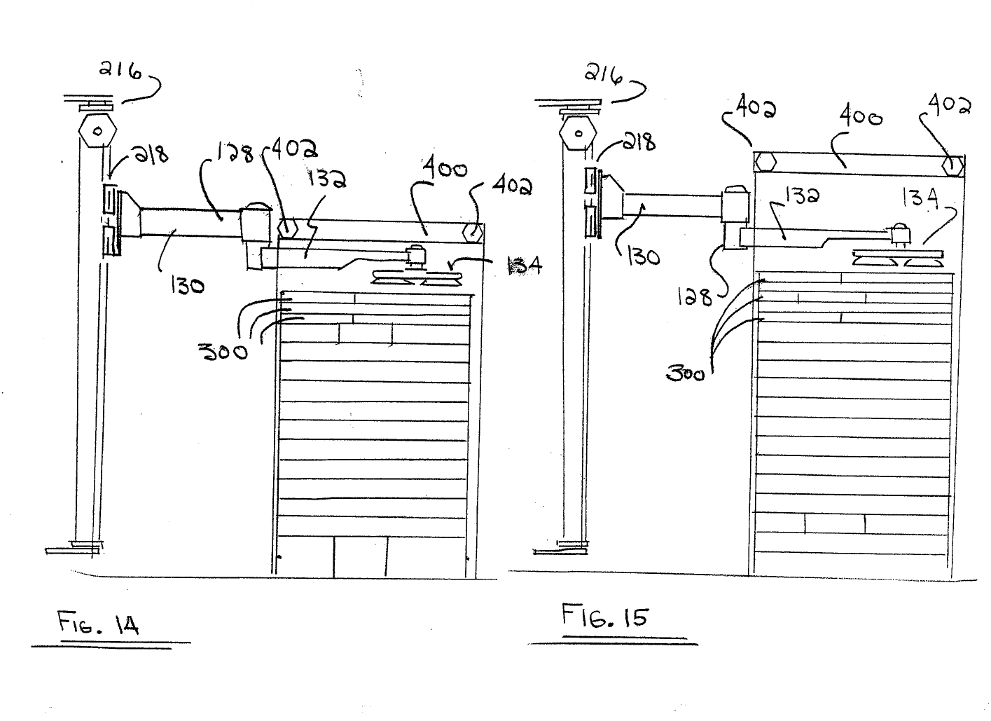

Referring now to FIGS. 13-15, another embodiment of the present invention is illustrated where the manipulator arm 128 is mounted to a lift truck 200 including a vertically movable carriage 218 connected t a lift mast 216. The arm 128 is secured to the carriage 218 such that the arm 128 can be vertically positioned with respect to the lift truck 200 by moving the carriage 218 through the operation of a suitable motive mechanism (not shown) disposed on the lift mast 216 of the lift truck 200 and connected to the carriage 218 to move the arm 128 between raised and lowered positions, as shown in FIG. 13. By moving the carriage 218, the head 134 of the arm 128 can be properly positioned with regard to objects 300 disposed within a storage rack 400 having cross beam support members 402, such that the head 134 can grasp and move the objects 300 without interference from the rack structure 400, as shown in FIGS. 14 and 15.

To enable the head 134 of the arm 128 to be operated as desired, the lift truck 200 also includes a motor/compressor 222 operably connected to the arm 128 and head 134 to supply vacuum to the cups 136 on the head 134, and to move the arm 128 with respect to the carriage 218.

Various alternatives are contemplated as being within the scope of the following claims particularly pointing out and distinctly claiming the subject matter regarded as the invention.

What is claimed is:

1. A manipulator arm comprising:
a) a first section adapted to be secured to a lift truck;
b) a second section pivotally secured to the first section; and
c) a gripping head operably secured to the second section opposite the first section, wherein the head has an overall height of less than about fourteen (14) inches.

2. The arm of claim 1 wherein the gripping head has an overall height of approximately eight (8) inches.

3. A pickup head for a manipulator arm, the head comprising:
a) a frame adapted to be secured to the manipulator arm; and
b) at least one gripping assembly operably connected to the frame, wherein the overall height of the frame and the at least one gripping assembly does not exceed fourteen (14) inches.

4. A lift truck comprising:
a) a platform including a number of wheels and a motor operably connected to the wheels to cause the wheels to rotate;
b) a lift mast operably connected to the platform;
c) a manipulator arm operably connected to the lift mast opposite the platform; and
d) a pickup head operably connected to the manipulator arm opposite the mast, wherein the overall height of the lift head does not exceed fourteen (14) inches.
